(19) United States
(12) Patent Application Publication
(10) Pub. No.: US 2018/0269374 A1
(43) Pub. Date: Sep. 20, 2018

(54) PIEZOELECTRIC ELEMENT AND METHOD FOR MANUFACTURING THE SAME AND LIQUID DISCHARGE HEAD

(71) Applicant: CANON KABUSHIKI KAISHA, Tokyo (JP)

(72) Inventors: Hiroto Numazawa, Kawasaki-shi (JP); Minako Nakasu, Tokyo (JP); Motokazu Kobayashi, Yokohama-shi (JP); Yoshihiro Ohashi, Tokyo (JP); Hiroto Numazawa, Kawasaki-shi (JP)

(21) Appl. No.: 15/912,223

(22) Filed: Mar. 5, 2018

(30) Foreign Application Priority Data
Mar. 16, 2017 (JP) 2017-051538
Aug. 3, 2017 (JP) 2017-150906

(51) Int. Cl. H01L 41/047; H01L 41/27

(52) U.S. Cl. CPC H01L 41/0471; H01L 41/27

(57) ABSTRACT

A piezoelectric element has a first piezoelectric layer, a second piezoelectric layer on the first piezoelectric layer, and an electrode layer on the second piezoelectric layer, in which the first piezoelectric layer and the second piezoelectric layer have pores, and the porosity of the second piezoelectric layer is lower than the porosity near the interface on the second piezoelectric layer side of the first piezoelectric layer.

### BACKGROUND

### Field of the Disclosure

The present disclosure relates to a piezoelectric element and a method for manufacturing the same and a liquid discharge head.

### Description of the Related Art

As materials of a piezoelectric layer of a piezoelectric element, lead zirconate titanate (hereinafter also referred to as “PZT”) has been generally used. Recently, lead-free materials not containing Pb have also been developed considering the environment. The piezoelectric element has been used for an ink jet recording head, for example. Due to the fact that the piezoelectric element exhibits an electromechanical conversion function (pressure promoting displacement), ink is discharged from a discharge port. Examples of methods for forming the piezoelectric layer include, for example, a sputtering method, a sol-gel method, a metal organic deposition method (MOD method), and the like.

In the sol-gel method and the metal organic deposition method (MOD method), a coating liquid containing an organometallic compound and the like is applied, dried, and then fired to form a piezoelectric layer. Herein, the coating liquid contains an organic substance, and therefore the organic substance is burned in firing to be released to the outside of the system from a thin film, and then pores are formed where the organic substance is released. The pores are present in the piezoelectric layer and in the surface of the piezoelectric layer. Therefore, when an electrode layer is formed on the piezoelectric layer, a material of the electrode layer penetrates into the piezoelectric layer, and then electric leakage (electrodes are electrically bonded to each other) occurs, so that the piezoelectric layer cannot sufficiently exhibit the function in some cases. In particular, in order to use the piezoelectric element for a piezoelectric head or the like, the leak current is demanded to be 1×10⁻⁵ A/cm² or less.

As one of methods for preventing the electric leakage, it is considered to form an insulating layer on the piezoelectric layer. For example, Japanese Patent Laid-Open No. 5-124188 has proposed a method for covering the surface of the piezoelectric layer before providing the electrode layer with an insulating oxide layer. However, the method described in Japanese Patent Laid-Open No. 5-124188 requires preparation of materials and a coating liquid other than the materials and the coating liquid for the piezoelectric layer and the number of processes increases, and therefore the method has problems of complexity and the like.

### SUMMARY

The subject disclosure provides a piezoelectric element in which electric leakage is suppressed.

A piezoelectric element according to one embodiment is a piezoelectric element having a first piezoelectric layer, a second piezoelectric layer on the first piezoelectric layer, and an electrode layer on the second piezoelectric layer, in which the first piezoelectric layer and the second piezoelectric layer have pores, and the porosity of the second piezoelectric layer is lower than the porosity near the interface on the second piezoelectric layer side of the first piezoelectric layer.

A method for manufacturing a piezoelectric element according to one embodiment includes a process of applying a precursor coating liquid of the first piezoelectric layer on a substrate, followed by drying and firing, a process of applying a precursor coating liquid for the second piezoelectric layer on the first piezoelectric layer, followed by drying and firing, and a process of forming an electrode layer on the second piezoelectric layer.

Further features of the present disclosure will become apparent from the following description of exemplary embodiments with reference to the attached drawings.

### BRIEF DESCRIPTION OF THE DRAWINGS

FIG. 1 is a cross-sectional view illustrating an example of a piezoelectric element according to one embodiment of the subject disclosure.

FIG. 2 is a cross-sectional view illustrating one embodiment of an ink jet recording head as an example of a liquid discharge head according to this embodiment.

FIG. 3 is a transmission electron microscope photograph obtained by photographing the cross section of a substrate on which a first piezoelectric layer and a second piezoelectric layer are formed in Example 1.

### DESCRIPTION OF THE EMBODIMENTS

### Piezoelectric Element

A piezoelectric element according to this embodiment has a first piezoelectric layer, a second piezoelectric layer on the first piezoelectric layer, and an electrode layer on the second piezoelectric layer. Herein, the first piezoelectric layer and the second piezoelectric layer have pores. The porosity of the second piezoelectric layer is lower than the porosity near the interface on the second piezoelectric layer side of the first piezoelectric layer.

In the piezoelectric element according to this embodiment, the porosity of the second piezoelectric layer is lower than the porosity near the interface on the second piezoelectric layer side of the first piezoelectric layer, and therefore the penetration of a material of the electrode layer disposed on the second piezoelectric layer into the first piezoelectric layer through the second piezoelectric layer can be suppressed. Thus, a piezoelectric element is provided in which electric leakage between electrodes is suppressed and which has good piezoelectric characteristics. Hereinafter, an embodiment is described.

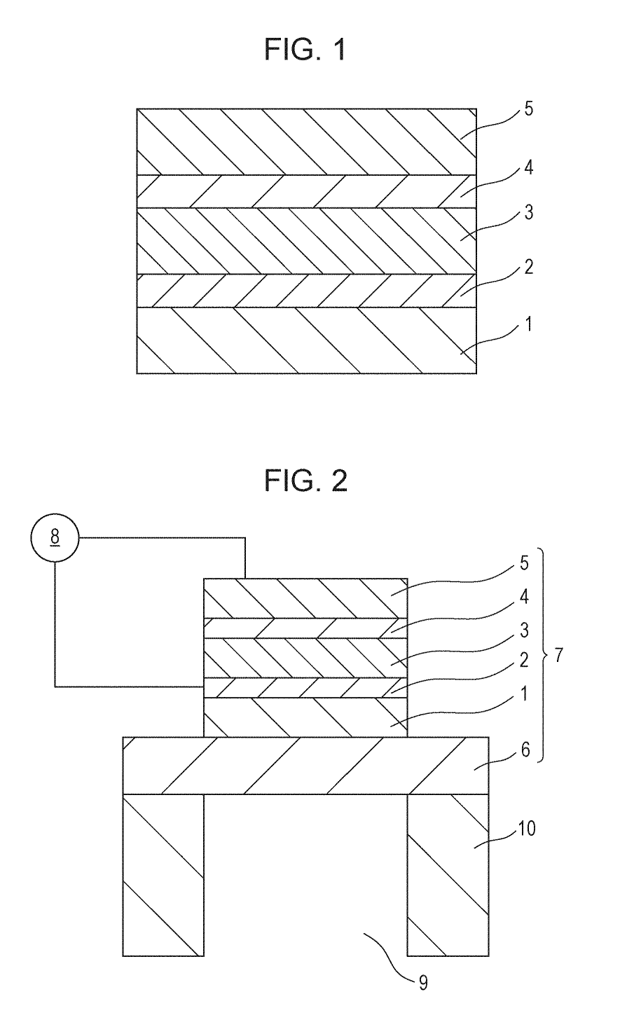

FIG. 1 illustrates an example of a piezoelectric element according to this embodiment. The piezoelectric element illustrated in FIG. 1 has a substrate 1, a lower electrode 2, a first piezoelectric layer 3, a second piezoelectric layer 4, and an upper electrode 5 in this order. In the piezoelectric element, the upper electrode 5 is equivalent to the electrode layer in this embodiment. The piezoelectric element may have other layers other than the substrate 1, the lower electrode 2, the first piezoelectric layer 3, the second piezoelectric layer 4, and the upper electrode 5. However, it is suitable that the lower electrode 2 and the first piezoelectric layer 3, the first piezoelectric layer 3 and the second piezoelectric layer 4, and the second piezoelectric layer 4 and the upper electrode 5 (electrode layer) are in contact with each other.

### Substrate

Materials of the substrate are not particularly limited and materials which are not deformed and melted in a firing process in piezoelectric layer formation are suitable. When manufacturing a liquid discharge head using the piezoelectric element according to this embodiment, the substrate may also serve as a pressure chamber substrate for forming a pressure chamber or a diaphragm. The substrate is suitably a semiconductor substrate containing silicon (Si), tungsten (W), and the like or a substrate containing heat resistant stainless steel (SUS), for example. As materials of the substrate, ceramics, such as zirconia, alumina, and silica, may be used. The materials of the substrate may be used alone or in combination of two or more kinds thereof. The substrate may have a multilayer configuration containing a laminate of two or more of the materials mentioned above.

### Electrode Layer

Materials of an electrode layer (equivalent to the upper electrode 5 in the piezoelectric element illustrated in FIG. 1) are not particularly limited and are selected as appropriate from materials usually used for electrodes of the piezoelectric element. For example, metals, such as Ti, Pt, Ta, Ir, Sr, In, Sn, Au, Al, Fe, Cr, and Ni, and oxides thereof are mentioned. The materials may be used alone or in combination of two or more kinds thereof. The electrode layer may have a multilayer configuration containing a laminate of two or more of the materials mentioned above. The thickness of the electrode layer is not particularly limited and can be set to 5 to 2000 nm, for example. In the piezoelectric element illustrated in FIG. 1, the upper electrode 5 is equivalent to the electrode layer in this embodiment and the lower electrode 2 can also have the same configuration as that of the electrode layer.

### First Piezoelectric Layer, Second Piezoelectric Layer

The first piezoelectric layer and the second piezoelectric layer have pores. In this embodiment, the porosity of the second piezoelectric layer is lower than the porosity near the interface on the second piezoelectric layer side of the first piezoelectric layer. Due to the fact that the porosity of the second piezoelectric layer is lower than the porosity near the interface on the second piezoelectric layer side of the first piezoelectric layer, the penetration of the material of the electrode layer into the piezoelectric layer can be suppressed and electric leakage can be suppressed. The porosity of the second piezoelectric layer is lower than the porosity near the interface on the second piezoelectric layer side of the first piezoelectric layer by preferably 3% or more and more preferably 5% or more.

The “porosity near the interface on the second piezoelectric layer side of the first piezoelectric layer” indicates the porosity in a region to a 20% depth of the thickness of the entire first piezoelectric layer toward the first piezoelectric layer side with the contact interface of the second piezoelectric layer and the first piezoelectric layer as the starting point. The porosity can be two-dimensionally estimated by observing the cross sections of the first piezoelectric layer and the second piezoelectric layer under an electron microscope or the like. Specifically, the porosity is calculated by a method described later.

The porosity of the second piezoelectric layer is preferably 40% or less, more preferably 35% or less, and still more preferably 30% or less. Due to the fact that the porosity of the second piezoelectric layer is 40% or less, the electric leakage between electrodes is further suppressed. The lower limit of the porosity of the second piezoelectric layer is not particularly limited. The porosity near the interface on the second piezoelectric layer side of the first piezoelectric layer is preferably 30 to 50%, more preferably 32 to 45%, and still more preferably 35 to 40%. Due to the fact that the porosity near the interface on the second piezoelectric layer side of the first piezoelectric layer is 30% or more, the generation of cracks (fracture) due to the influence of stress can be suppressed. Due to the fact that the porosity near the interface on the second piezoelectric layer side of the first piezoelectric layer is 50% or less, the electric leakage between electrodes is further suppressed.

The pore diameter of the second piezoelectric layer is suitably smaller than the pore diameter near the interface on the second piezoelectric layer side of the first piezoelectric layer. Due to the fact that the pore diameter of the second piezoelectric layer is smaller than the pore diameter near the interface on the second piezoelectric layer side of the first piezoelectric layer, the penetration of the material of the electrode layer into the piezoelectric layer can be further suppressed and the electric leakage can be further suppressed. The pore diameter of the second piezoelectric layer is smaller than the pore diameter near the interface on the second piezoelectric layer side of the first piezoelectric layer by preferably 50 nm or more and more preferably 100 nm or more.

The “pore diameter near the interface on the second piezoelectric layer side of the first piezoelectric layer” indicates the average of the diameters of pores present in a region to a 20% depth of the thickness of the entire first piezoelectric layer toward the first piezoelectric layer side with the contact interface of the second piezoelectric layer and the first piezoelectric layer as the starting point. The pore diameter can be two-dimensionally estimated by observing the cross sections of the first piezoelectric layer and the second piezoelectric layer under an electron microscope or the like. Specifically, the pore diameter is calculated by a method described later.

The pore diameter of the second piezoelectric layer is preferably 5 to 40 nm, more preferably 10 to 35 nm, and still more preferably 15 to 30 nm. Due to the fact that the pore diameter of the second piezoelectric layer is 5 nm or more, the generation of cracks (fracture) due to the influence of stress can be suppressed. Due to the fact that the pore diameter of the second piezoelectric layer is 40 nm or less, the electric leakage between electrodes is further suppressed. The pore diameter near the interface on the second piezoelectric layer side of the first piezoelectric layer is preferably 100 to 200 nm, more preferably 110 to 180 nm, and still more preferably 120 to 160 nm. Due to the fact that the pore diameter near the interface on the second piezoelectric layer side of the first piezoelectric layer is 100 nm or more, the generation of cracks (fracture) due to the influence of stress can be suppressed. Due to the fact that the pore diameter near the interface on the second piezoelectric layer side of the first piezoelectric layer is 200 nm or less, the electric leakage between electrodes is further suppressed.

The porosity and the pore diameter are controllable by varying the decomposition temperature and the content of organic components in a coating liquid for forming each layer, the temperature and the time in the drying and the firing, and the like.

It is suitable that the porosity of the first piezoelectric layer decreases in the thickness direction of the first piezoelectric layer from the second piezoelectric layer side because the penetration of the material of the electrode layer into the piezoelectric layer can be further suppressed. It is suitable that the pore diameter of the first piezoelectric layer decreases in the thickness direction of the first piezoelectric layer from the second piezoelectric layer side because the penetration of the material of the electrode layer into the piezoelectric layer can be further suppressed. These matters can be confirmed by observing the cross section of the first piezoelectric layer under an electron microscope or the like, equally dividing the first piezoelectric layer into five regions in the thickness direction, and then measuring the porosity and the pore diameter in each region. Specifically, the matters can be confirmed by a method described later.

The first piezoelectric layer and the second piezoelectric layer can contain, for example, BiNaTiO₃—BaTiO₃ which is a solid solution of an oxide of Bi, Na, and Ti and an oxide of Ba and Ti, BaCaTiZrO₃ which is an oxide of Ba, Ca, Ti, and Zr, KNaNbO₃ which is an oxide of K, Na, and Nb, NaNbO₃ which is an oxide of Na and Nb, and the like. The first piezoelectric layer and the second piezoelectric layer may also contain lead zirconate titanate (PZT) which is an oxide of Pb, Ti, and Zr. The first piezoelectric layer and the second piezoelectric layer may also contain one kind thereof or two or more kinds thereof. In particular, the first piezoelectric layer and the second piezoelectric layer suitably do not contain lead and suitably contain at least titanium and barium from the viewpoint of influence on the environment.

The first piezoelectric layer and the second piezoelectric layer may be doped with trace elements other than the main elements mentioned above. Examples of elements usable as dopants include La, Ca, Sr, Ba, Sn, Th, Y, Sm, Ce, Bi, Sb, Nb, Ta, W, Mo, Cr, Co, Ni, Fe, Cu, Si, Ge, Sc, Mg, Mn, and the like, for example. One kind or two or more kinds of these elements may be added.

The thickness of the first piezoelectric layer is not particularly limited and is preferably 100 to 3900 nm, more preferably 1000 to 3000 nm, and still more preferably 1500 to 2500 nm. The thickness of the second piezoelectric layer is not particularly limited and is preferably 50 to 200 nm, more preferably 60 to 180 nm, and still more preferably 70 to 150 nm. The total thickness of the first piezoelectric layer and the second piezoelectric layer is preferably 200 to 4000 nm, more preferably 500 to 3500 nm, and still more preferably 500 to 3000 nm from the viewpoint of exhibiting desired performance.

It is suitable from the viewpoint of suppression of cracks (fracture) in the layers that at least one of the first piezoelectric layer and the second piezoelectric layer contains a plurality of layers. For example, the first piezoelectric layer can contain 5 to 20 layers and the second piezoelectric layer can contain 2 to 4 layers. The plurality of layers are the same and refer to a layer formed by overlapping a plurality of single layers formed by applying a coating liquid for a piezoelectric layer, and then drying/firing the same in a method for manufacturing a piezoelectric element described later.

### Other Layers

The piezoelectric element according to this embodiment may have an intermediate layer to be disposed for improving the adhesiveness between the substrate and the lower electrode, a seed layer for improving orientation control and wettability, a barrier layer, and the like, for example, besides the layers described above.

### Method for Manufacturing Piezoelectric Element

A method for manufacturing a piezoelectric element according to this embodiment includes a process of applying a precursor coating liquid (hereinafter also referred to as “coating liquid”) for the first piezoelectric layer onto a substrate, followed by drying and firing, a process of applying a precursor coating liquid for the second piezoelectric layer onto the first piezoelectric layer, followed by drying and firing, and a process of forming an electrode layer on the second piezoelectric layer. According to the above-described method, the piezoelectric element according to this embodiment can be easily manufactured.

The piezoelectric element according to this embodiment can be manufactured by the following method, for example. First, a lower electrode is formed on a substrate. The lower electrode may be formed by applying and firing the metals and the oxides for use in an electrode layer mentioned above by a sol-gel method or the like or may be formed by sputtering, vapor deposition, or the like. The lower electrode may be patterned into a desired shape.

Next, the first piezoelectric layer and the second piezoelectric layer are formed in this order on the lower electrode. The first piezoelectric layer and the second piezoelectric layer can be formed by a sol-gel method, a metal organic deposition method (MOD method), or the like, for example. The sol-gel method includes applying a solution or a dispersion liquid containing hydrolytic compounds of metals serving as raw materials, partial hydrolysates thereof, or partial polycondensates thereof onto a substrate, drying a coating film, and then heating the same in the air to form a film, for example. Thereafter, the film is fired at a temperature equal to or higher than the crystallization temperature to be crystallized, whereby a piezoelectric layer can be formed. As hydrolytic metal compounds serving as raw materials, organometallic compounds, such as metal alkoxides, partial hydrolysates thereof, or partial polycondensates thereof, are used. The sol-gel method can form a piezoelectric layer at low cost and simply.

The MOD method which is a method similar to the sol-gel method includes applying a solution containing pyrolytic organometallic compounds (metal complex, metal organic acid salt), e.g., β-diketone complexes and carboxylates of metals, onto a substrate, and then heating the same in the air or oxygen. Thus, the evaporation of the solvent and the pyrolysis of the organometallic compound in the coating film are caused and firing is performed at a temperature equal to or higher than the crystallization temperature for crystallization, whereby a piezoelectric layer can be formed.

The coating liquid to be used in the sol-gel method is manufactured through the formation of a composite compound in which metal elements are bonded to each other by heating raw material compounds containing desired metal elements in an organic solvent to cause hydrolysis and a chemical reaction, a reaction of exchanging functional groups for stabilization, and the like, for example. The coating liquid to be used in the MOD method is manufactured by dissolving raw material compounds in an organic solvent without particularly causing hydrolysis and a chemical reaction, for example.

A piezoelectric layer formed by the sol-gel method is likely to be porous and a piezoelectric layer formed by the MOD method is likely to be dense. Therefore, the method according to this embodiment suitably includes a process of forming a first piezoelectric layer by the sol-gel method from the viewpoint of setting the porosity of the second piezoelectric layer to be lower than the porosity near the interface on the second piezoelectric layer side of the first piezoelectric layer. The above-described method suitably includes a process of forming the second piezoelectric layer by the metal organic deposition method (MOD method).

As the coating liquids to be used for the formation of the first piezoelectric layer and the second piezoelectric layer, coating liquids containing a composite precursor of BiNaTiO₃—BaTiO₃ which is a solid solution of an oxide of Bi, Na, and Ti and an oxide of Ba and Ti, a composite precursor of BaCaTiZrO₃ which is an oxide of Ba, Ca, Ti, and Zr, a composite precursor of KNaNbO₃ which is an oxide of K, Na, and Nb, a composite precursor of NaNbO₃ which is an oxide of Na and Nb, and the like are usable, for example. The coating liquids may also contain a composite precursor of lead zirconate titanate (PZT) which is an oxide of Pb, Ti, and Zr. The coating liquids may also contain the elements usable as the dopants described above.

Examples of the organic solvents for use in the preparation of the coating liquids include, for example, alcohol-based solvents, such as methanol, ethanol, n-propanol, isopropanol, n-butanol, s-butanol, and t-butanol, ether-based solvents, such as tetrahydrofuran and 1,4-dioxane, cellosolve-based solvents, such as 2-methoxyethanol, 2-ethoxyethanol, and 1-methoxy-2-propanol, amide-based solvents, such as N,N-dimethyl formamide, N,N-dimethyl acetamide, and N-methyl pyrrolidone type, nitrile-based solvents, such as acetonitrile, diethylene glycol monoethyl ether, diethylene glycol monoethyl ether acetate, diethylene glycol monobutyl ether, diethylene glycol monobutyl ether acetate, and the like. Among the above, the alcohol-based solvents are suitable as the organic solvent. These organic solvents can be used alone or in combination of two or more kinds thereof. The amount of the organic solvent to be used is preferably 5 molar times to 200 molar times and more preferably 10 molar times to 100 molar times the raw material compound.

As the raw material compounds for use in the preparation of the coating liquids, alkoxide compounds of the metals mentioned above and salts of the metals mentioned above are usable. Among the above, alkoxide compounds and organometallic salts are suitable as the raw material compounds. For example, when forming a piezoelectric layer containing PZT, examples of alkoxide compounds of Pb usable as the raw material compounds include lead 2-ethoxy ethoxide, lead methoxide, lead ethoxide, lead n-propoxide, lead i-propoxide, lead n-butoxide, lead i-butoxide, lead t-butoxide, and the like. Moreover, various alkoxides, alkyl substitution products thereof those, and the like are mentioned. Moreover, examples of metal salts of Pb include inorganic salt compounds, such as oxides, chlorides, nitrates, and the like of lead. Examples of organic salt compounds include various kinds of carboxylates, such as formates, acetates, and propionates of lead, hydroxycarboxylate, an acetylacetonato complex, and the like. Alkoxide compounds or metal salts can be similarly used for Zr, Ti, and the other metals (La, Mg, Nb, and the like).

From the viewpoint of uniformly mixing the raw material compounds, organometallic compounds soluble in an organic solvent to be used are suitably used as the raw material compounds. When the raw material compounds contain water of crystallization, the raw material compounds are suitably heated at a temperature lower than the decomposition temperature for dehydration beforehand for use. This is because, when the raw material compounds are compounded in the following heating process, the raw material compounds may partially cause hydrolysis during compounding due to the presence of the water of crystallization to cause variation in the composition in some cases.

The charging ratio of the raw material compounds may be the same as that of the target metal composition. When the raw material compounds contain Pb, the disappearance of the Pb occurs in a firing process in film forming in some cases, and therefore the amount of the Pb raw material compound is suitably increased beforehand in the preparation of the coating liquid. Specifically, the amount of the Pb raw material compound is suitably increased within the range of 5 to 30% in terms of the metal molar ratio.

A method for preparing the coating liquid for use in the sol-gel method can stabilize the coating liquid by adding a stabilizer into a raw material mixed liquid. The stabilizer can slowly advance the formation of metal-oxygen-metal bond as a whole in compounding by heating. Usable as the stabilizer are β-diketones (for example, acetylacetone, heptafluorobutanoylpivaloylmethane, dipivaloylmethane, trifluoroacetylacetone, benzoylacetone, and the like), ketonic acids (for example, acetoacetic acid, propionyl acetate, benzoylacetic acid, and the like), lower alkyl esters, such as ethyl, propyl, and butyl of these ketonic acids, oxyacids (for example, lactic acid, glycolic acid, α-oxy butyric acid, salicylic acid, and the like), lower alkyl esters of these oxyacids, oxyketones (for example, diacetone alcohol, acetoin, and the like), α-amino acids (for example, glycine, alanine, and the like), and alkanolamines (for example, diethanolamine, triethanolamine, and monoethanolamine). These substances may be used alone or in combination of two or more kinds thereof. When using the other stabilizers in combination, the total addition amount of the stabilizers is preferably 0.05 molar times to 5 molar times and more preferably 0.1 molar times and 1.5 molar times the number of moles of all the metal atoms.

By heating the raw material mixed liquid to which the stabilizer is added, composite metal compounds containing the metal elements are obtained. According to the heating process, metal compounds react with each other or coordinated to be compounded. The heating temperature can be set to 120° C. or higher and lower than the boiling point of an organic solvent to be used, for example. The heating time is not particularly limited and is suitably about several hours to over ten hours.

After the heating process, water may be added for hydrolysis. The amount of the water to be added in the hydrolysis is preferably 0.05 to 30 molar times and more preferably 0.5 to 15 molar times the raw material compounds, for example. A water-soluble organic solvent, for example, an alcohol-based solvent, may be added with water. The hydrolysis may be carried out in the presence of an acid catalyst and/or a base catalyst. Examples of the acid catalyst include metal salts, halides, mineral acids, such as sulfuric acid, nitric acid, and hydrochloric acid, and organic acids, such as acetic acid. Examples of the base catalyst include ammonia which can be easily removed by drying and firing. The hydrolysis can also be performed at room temperature (25° C.) and is suitably performed under heating in order to shorten the reaction time. For example, the hydrolysis can be performed at a temperature of 60° C. or higher. The hydrolysis may be performed at normal pressure or may be performed under pressurization. Thereafter, an organic solvent, resin, a surfactant, and the like may be added to increase the coatability and improve liquid physical properties.

First, the coating liquid for the first piezoelectric layer can be applied onto the lower electrode formed on the substrate, and then dried. As a coating method, spin coating, dip coating, bar coating, spray coating, and the like are usable. The drying after the coating can be performed at a temperature of 100° C. or higher and 400° C. or less. By performing the drying at a temperature of 100° C. or higher, the drying time can be shortened. The thickness per layer after the drying is preferably 50 to 1000 nm. The coating liquid may be applied again onto the film after drying to form a laminated structure containing a plurality of layers. Subsequently, firing can be performed. For the firing, a drier, a hot plate, a tube furnace, an electric furnace, and the like are usable. The firing temperature can be set within the range of 600 to 1000° C. The coating liquid may be applied again onto the film after the firing, dried, and then fired to thereby form a laminated structure containing a plurality of layers. The gas present on the substrate surface from the drying process to the firing process suitably contains oxygen. The oxygen concentration of the gas is preferably 20 to 100%.

Next, the coating liquid for the second piezoelectric layer can be applied onto the first piezoelectric layer, and then dried. The coating liquid for the second piezoelectric layer may be the same as the coating liquid for the first piezoelectric layer and may be different in the materials, the composition ratio, the concentration, and the like from the coating liquid for the first piezoelectric layer. For example, a coating liquid containing a KNaNbO₃ composite precursor may be used as the coating liquid for the first piezoelectric layer and a coating liquid containing a BaTiO₃ composite precursor may be used as the coating liquid for the second piezoelectric layer. A coating method of the coating liquid for the second piezoelectric layer and the drying temperature may be the same as those of the coating liquid for the first piezoelectric layer. The thickness per layer after the drying is preferably 10 to 100 nm. The coating liquid may be applied again onto the film after the drying, and then dried to form a laminated structure containing a plurality of layers. Subsequently, firing can be performed in the same manner as in the formation of the first piezoelectric layer. The coating liquid may be applied again onto the film after the firing, dried, and then fired to thereby form a laminated structure containing a plurality of layers.

Next, an upper electrode is formed on the second piezoelectric layer. The upper electrode can be formed by the same method as that of the lower electrode described above. Thus, a piezoelectric element according to this embodiment is obtained.

Before applying the coating liquid for the first piezoelectric layer onto the lower electrode, a seed layer may be provided in order to improve the orientation control or the wettability. A coating liquid for the seed layer can be prepared by the same method as that of the coating liquid for the piezoelectric layer. The orientation control or the wettability can be controlled by the kind of metal alkoxide and/or metal salt, the kind of a solvent, the concentration of water to metal alkoxide and/or metal salt, the concentration of metal alkoxide and/or metal salt, a catalyst, the stabilization by chelation of metal alkoxide and/or metal salt, and the like.

### Liquid Discharge Head

A liquid discharge head according to this embodiment has a piezoelectric actuator having the piezoelectric element according to this embodiment and discharges liquid by driving of the piezoelectric actuator. In the liquid discharge head according to this embodiment, the piezoelectric actuator to be used for the discharge of liquid has the piezoelectric element according to this embodiment, and therefore the electric leakage between electrodes is suppressed, the piezoelectric element shows good piezoelectric characteristics, and the discharge of liquid can be stably performed with good accuracy. Examples of a typical application example of the liquid discharge head according to this embodiment include an ink jet recording head to be applied to an ink jet apparatus discharging ink to perform recording. However, the liquid discharge head is not limited to the use and is applicable to an apparatus, such as a printer, a copying machine, a facsimile having a communication system, and a word processor having a printer portion and further an industrial recording apparatus combined with various processing devices in complex manner. For example, the liquid discharge head is also usable for biochip production, electronic circuit printing, semiconductor substrate production, and the like.

An ink jet recording head which is an example of the liquid discharge head according to this embodiment can have, for example, a discharge port formation member having a discharge port discharging ink and a pressure chamber communicating with the discharge port and a piezoelectric actuator causing a capacity variation for discharging ink from the discharge port in the pressure chamber. The piezoelectric actuator can have a diaphragm having a first surface facing the pressure chamber and the piezoelectric element according to this embodiment to be provided on a second surface opposite to the first surface of the diaphragm. Hereinafter, an embodiment of the liquid discharge head according to this embodiment is described with reference to the drawings but this embodiment is not limited to the embodiment.

FIG. 2 illustrates one embodiment of an ink jet recording head which is an example of the liquid discharge head according to this embodiment. A discharge port formation member 10 has a plurality of discharge ports (not illustrated) discharging ink, a plurality of flow passages (not illustrated) individually communicating with the discharge ports, and a plurality of pressure chambers 9 individually communicating with the flow passages. A diaphragm 6 is provided so as to cover the entire surface facing the discharge ports of the discharge port formation member 10 and the upper surface openings of all the pressure chambers 9 of the discharge port formation member 10 are covered with the diaphragm 6. On the diaphragm 6, the piezoelectric element according to this embodiment for giving vibration driving force to the diaphragm 6 is attached and formed at positions individually corresponding to the pressure chambers 9. The piezoelectric element has a substrate 1, a lower electrode 2, a first piezoelectric layer 3, a second piezoelectric layer 4, and an upper electrode 5 in this order and configures a piezoelectric actuator 7 together with the diaphragm 6. By controlling a power supply 8 connected to the piezoelectric element and applying a voltage to the selected piezoelectric element, the piezoelectric element is displaced to vibrate the diaphragm 6. Thus, the capacity in the pressure chamber 9 of a portion corresponding to the vibration of the diaphragm 6 is varied, ink is discharged from the discharge port through the flow passage, and then printing is performed.

### EXAMPLES

Hereinafter, this embodiment is more specifically described with reference to Examples but this embodiment is not limited by the following Examples.

### Example 1

### Preparation of Coating Liquid for First Piezoelectric Layer

As a coating liquid for forming a first piezoelectric layer, a coating liquid in which the composition ratio of contained metals is represented by Ba/Ca/Ti/Zr=0.95/0.05/0.95/0.05 (molar ratio) was prepared by a sol-gel method. Specifically 0.0095 mol of barium diisopropoxide, 0.0005 mol of calcium diisobutoxide, 0.0095 mol of titanium tetraiso butoxide, and 0.0005 mol of zirconium tetraiso butoxide were mixed with 20 ml of 2-methoxyethanol and 20 ml of 3-methoxy-3-methylbutanol. The mixture was heated for 3 hours for refluxing to prepare the coating liquid for the first piezoelectric layer.

### Coating Liquid for Second Piezoelectric Layer

As a coating liquid for a second piezoelectric layer, BT-06 (Trade Name, manufactured by Kojundo Chemical Lab. Co., Ltd.) which is an MOD coat liquid containing BaTiO₃ was used.

### Preparation of Piezoelectric Element

As a substrate, a substrate was prepared in which a 500 nm thick silica (SiO₂) layer was provided on the surface of a silicon substrate having a diameter of 6 inches (15 cm) by thermal oxidation. On the silica layer of the substrate, Ti was formed into a film by a sputtering method without heating the substrate to form a 10 nm thick intermediate layer. Subsequently, Pt was formed into a film on the intermediate layer by a sputtering method without heating the substrate to form a 150 nm thick lower electrode.

Next, the coating liquid for a first piezoelectric layer was applied onto the lower electrode with a spin coater (4000 rpm, 15 seconds). Thereafter, the substrate was placed on a hot plate heated to 380° C. for 5 minutes to be dried. Subsequently, firing was performed at 1000° C. for 10 minutes using an electric furnace in the oxygen environment for crystallization to form a first layer of the first piezoelectric layer. On the first layer of the first piezoelectric layer, the coating liquid for the first piezoelectric layer was applied and fired under the same conditions as those of the first layer to form a second layer. The same operation was further repeated 12 times to form a 2000 nm thick first piezoelectric layer containing 14 layers.

Next, BT-06 as the coating liquid for a second piezoelectric layer was applied onto the first piezoelectric layer with a spin coater (3000 rpm, 15 seconds). Thereafter, the substrate was placed on a hot plate heated to 200° C. for 10 minutes to be dried. Subsequently, firing was performed at 800° C. for 5 minutes using an electric furnace in the oxygen environment to form a first layer of the second piezoelectric layer. The top of the first layer of the second piezoelectric layer was subjected to the same process again, whereby a 100 nm thick second piezoelectric layer containing two layers was formed.

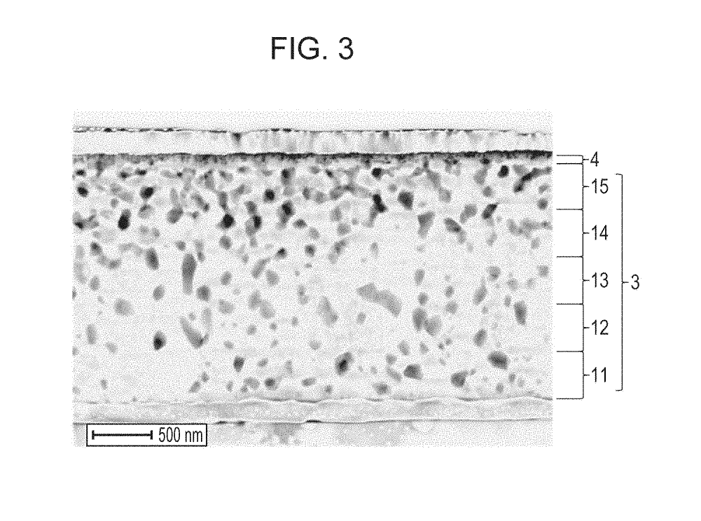

Herein, the cross section of the substrate was observed under a transmission electron microscope. FIG. 3 shows a photograph of the obtained cross section. As shown in FIG. 3, the first piezoelectric layer 3 was equally divided in the thickness direction into five regions of a A region 11, a B region 12, a C region 13, a D region 14, and an E region 15 in order from the substrate side, and then the porosity and the pore diameter each were calculated by image processing for the five regions and the second piezoelectric layer 4. The results are shown in Table 1. The calculation of the pore diameter and the porosity by image processing was specifically performed by the following methods. A cross-sectional photograph of the piezoelectric layer was taken by an electron microscope, and then an image thereof was binarized to be clearly separated so that pores and a dense portion can be distinguished. The longest diagonal line of the pores was defined as the pore diameter. Moreover, the ratio of the area of the pores to the area of the entire piezoelectric layer in the image was calculated to be defined as the porosity. As the cross-sectional photograph of the piezoelectric layer used for the calculation, a photograph capturing a region from the lower electrode to an upper portion of the second piezoelectric layer was used. The number of pores used for the calculation was set to 100 or more.

Next, gold was formed into a film on the second piezoelectric layer by sputtering to form a 100 nm thick upper electrode. A piezoelectric element was produced by the above-described processes.

### Evaluation

Between the lower electrode and the upper electrode of the piezoelectric element, an electric field was applied at a field intensity of 20 kV/cm, and then a leak current was measured. The results are shown in Table 2.

### Example 2

A piezoelectric element was manufactured and evaluated in the same manner as in Example 1, except forming a 100 nm thick second piezoelectric layer using, in place of the BT-06, a coating liquid obtained by adding 4 ml of 2-methoxyethanol in 1 ml of the coating liquid for the first piezoelectric layer for dilution as a coating liquid for the second piezoelectric layer. The results are shown in Table 2.

### Comparative Example 1

A piezoelectric element was manufactured and evaluated in the same manner as in Example 1, except not providing a second piezoelectric layer.

TABLE 1

| | | Example 1 | | Example 2 | |
|---|---|---|---|---|---|
| | | | Pore | | Pore |
| | | Porosity | diameter | Porosity | diameter |
| | | (%) | (nm) | (%) | (nm) |
| First | A region | 12 | 70 | 12 | 70 |
| piezoelectric | B region | 17 | 85 | 17 | 85 |
| layer | C region | 19 | 100 | 19 | 100 |
| | D region | 27 | 105 | 27 | 105 |
| | E region | 35 | 140 | 35 | 140 |

| | | | | |
|---|---|---|---|---|
| Second piezoelectric | 30 | 25 | 15 | 8 |
| layer | | | | |

TABLE 2

| | Leak current |
|---|---|
| | (×10⁻⁶ A/cm²) |
| Example 1 | 5.2 |
| Example 2 | 9.1 |
| Comparative | 2000 |
| Example 1 | |

Table 2 showed that the leak current is 1×10⁻⁵ A/cm² or less in Examples 1 and 2, and thus electric leakage was sufficiently suppressed.

This embodiment can provide a piezoelectric element in which electric leakage is suppressed.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2017-051538 filed Mar. 16, 2017 and No. 2017-150906 filed Aug. 3, 2017, which are hereby incorporated by reference herein in their entirety.

What is claimed is:

1. A piezoelectric element comprising:
a first piezoelectric layer;
a second piezoelectric layer on the first piezoelectric layer; and
an electrode layer on the second piezoelectric layer, wherein
the first piezoelectric layer and the second piezoelectric layer have pores, and
porosity of the second piezoelectric layer is lower than porosity near an interface on a side of the second piezoelectric layer of the first piezoelectric layer.

2. The piezoelectric element according to claim 1, wherein
the porosity of the second piezoelectric layer is 40% or less, and
the porosity near the interface on the second piezoelectric layer side of the first piezoelectric layer is 30 to 50%.

3. The piezoelectric element according to claim 1, wherein
a pore diameter of the second piezoelectric layer is smaller than a pore diameter near the interface on the second piezoelectric layer side of the first piezoelectric layer.

4. The piezoelectric element according to claim 1, wherein
the pore diameter of the second piezoelectric layer is 5 to 40 nm, and
the pore diameter near the interface on the second piezoelectric layer side of the first piezoelectric layer is 100 to 200 nm.

5. The piezoelectric element according to claim 1, wherein
at least one of the first piezoelectric layer and the second piezoelectric layer contains a plurality of layers.

6. The piezoelectric element according to claim 1, wherein
a total thickness of the first piezoelectric layer and the second piezoelectric layer is 200 to 4000 nm.

7. The piezoelectric element according to claim 1, wherein
the first piezoelectric layer and the second piezoelectric layer contain at least titanium and barium.

8. A method for manufacturing a piezoelectric element, the piezoelectric element comprising:
a first piezoelectric layer;
a second piezoelectric layer on the first piezoelectric layer; and
an electrode layer on the second piezoelectric layer, wherein
the first piezoelectric layer and the second piezoelectric layer have pores, and
porosity of the second piezoelectric layer is lower than porosity near an interface on a side of the second piezoelectric layer of the first piezoelectric layer,
the method comprising:
applying a precursor coating liquid for the first piezoelectric layer onto a substrate, followed by drying and firing;
applying a precursor coating liquid for the second piezoelectric layer onto the first piezoelectric layer, followed by drying and firing; and
forming an electrode layer on the second piezoelectric layer.

9. The method for manufacturing the piezoelectric element according to claim 8 comprising:
forming the first piezoelectric layer by a sol-gel method.

10. The method for manufacturing the piezoelectric element according to claim 8 comprising:
forming the second piezoelectric layer by a metal organic deposition method.

11. A liquid discharge head comprising:
a piezoelectric actuator having a piezoelectric element, the piezoelectric element comprising:
a first piezoelectric layer;
a second piezoelectric layer on the first piezoelectric layer; and
an electrode layer on the second piezoelectric layer, wherein
the first piezoelectric layer and the second piezoelectric layer have pores, and
porosity of the second piezoelectric layer is lower than porosity near an interface on a side of the second piezoelectric layer of the first piezoelectric layer, and
discharging liquid by driving of the piezoelectric actuator.
